(19) United States
(12) Patent Application Publication
(10) Pub. No.: US 2006/0151862 A1
(43) Pub. Date: Jul. 13, 2006

(54) Lead-frame-based semiconductor package and lead frame thereof

(75) Inventors: Yu-Wei Lin, Taichung (TW); Fu-Di Tang, Taichung (TW); Chun-Yuan Li, Taichung (TW); Terry Tsai, Taichung (TW); Yu-Ting Ho, Taichung (TW)

Correspondence Address: THE LAW OFFICES OF MIKIO ISHIMARU, 333 W. EL CAMINO REAL, SUITE 330, SUNNYVALE, CA, 94087, US

(73) Assignee: SILICONWARE PRECISON INDUSTRIES CO., LTD., Taichung Hsien (TW)

(21) Appl. No.: 11/071,389

(22) Filed: Mar. 2, 2005

(30) Foreign Application Priority Data
Jan. 11, 2005 (TW) 094100697

(51) Int. Cl. H01L 23/495

(52) U.S. Cl. 257/676

(57) ABSTRACT

A lead-frame-based semiconductor package and a lead frame thereof are proposed. The semiconductor package includes: the lead frame having at least one die pad and a plurality of leads around the die pad, wherein a plurality of grooves and runners are formed on a surface of the die pad, and each of the grooves is connected to an edge of the die pad by at least one of the runners; at least one chip mounted on the other surface of the die pad and electrically connected to the plurality of leads; and an encapsulant for encapsulating the chip, with the runners and grooves being exposed from the encapsulant. Thus, the flash problem in the prior art can be solved by means of the runners and grooves.

### FIELD OF THE INVENTION

The present invention relates to lead-frame-based semiconductor packages and lead frames thereof, and more particularly, to a lead-frame-based semiconductor package having flash runners, and a lead frame of the semiconductor package.

### BACKGROUND OF THE INVENTION

A conventional semiconductor package using a lead frame as a chip carrier, such as a quad flat package (QFP) or quad flat non-leaded (QFN) package, is fabricated by the steps of mounting a semiconductor chip on the lead frame that comprises a die pad and a plurality of leads; electrically connecting bond pads on a surface of the chip to the corresponding leads via a plurality of gold wires; and encapsulating the chip and the gold wires via an encapsulant, such that the lead-frame-based semiconductor package is formed. Further, a surface of the die pad can be exposed from the encapsulant so as to accelerate dissipation of heat from the chip via the die pad.

However, there is a flash issue for fabricating the encapsulant of the foregoing conventional semiconductor package occurred as shown in FIGS. 1A and 1B (taking a QFN semiconductor package as an example). The lower surface 52 of the die pad 51 is accidentally not in tight contact with the lower mold and causes gaps therebetween, and an encapsulating resin would flow through the gap and form flashes 53 on the lower surface 52 of the die pad 51. This not only impairs the appearance but also requires an additional deflashing process, thereby increasing the fabrication cost and affecting the heat dissipating efficiency.

U.S. Pat. No. 6,204,553 has disclosed a solution to the flash problem. As shown in FIGS. 2A and 2B, a plurality of grooves 63 are formed on a lower surface 62 of a die pad 61 and arranged in a square shape, wherein the adjacent grooves 63 are spaced by a constant distance and have the same depth. Therefore, during the molding process, flashes 65 can flow into the grooves 63 without contaminating the lower surface 62 of the die pad 61 so as to solve the foregoing flash problem.

However, the above conventional method still has a drawback that the flashes 65 can only flow into the nearby grooves 63 but not be evenly distributed, that is, the grooves 63 do not provide a flow guiding and diversion function. This thereby causes uneven distribution of the flashes 65 in the grooves 63 as shown in FIG. 3A, and still leads to the problems in impaired appearance and quality. Moreover, as the depth and width of the grooves 63 are limited, the flashes 65 if being in an excess amount may possibly exceed capacity of the grooves 63 and flash to the lower surface 62 of the die pad 61 as shown in FIG. 3B. In such case, the additional deflashing process is required to remove the flashes 65. Thus, this technology still cannot completely solve the conventional flash problem.

Therefore, the problem to be solved here is to provide a lead-frame-based semiconductor package, which can completely solve the problem of flashes on a lower surface of a die pad, thereby keeping the heat dissipating efficiency and saving cost of an unnecessary deflashing process.

### SUMMARY OF THE INVENTION

In light of the above drawbacks in the prior art, an objective of the present invention is to provide a lead-frame-based semiconductor package and a lead frame thereof, so as to prevent flashes from occurrence.

Another objective of the present invention is to provide a lead-frame-based semiconductor package and a lead frame thereof, which can simplify the fabrication processes.

Still another objective of the present invention is to provide a lead-frame-based semiconductor package and a lead frame thereof, which can reduce the fabrication cost.

A further objective of the present invention is to provide a lead-frame-based semiconductor package and a lead frame thereof, so as to enhance adhesion between an encapsulant and the lead frame.

In accordance with the above and other objectives, the present invention proposes a lead-frame-based semiconductor package, comprising: a lead frame having at least one die pad and a plurality of leads around the die pad, wherein a plurality of grooves and runners are formed on a lower surface of the die pad, and each of the grooves is connected to an edge of the die pad by at least one of the runners; at least one chip mounted on an upper surface of the die pad, and electrically connected to the plurality of leads; and an encapsulant for encapsulating the chip, with the grooves and runners being exposed from the encapsulant.

The present invention also proposes a lead frame, comprising: at least one die pad formed with a plurality of grooves and runners on a surface thereof, wherein each of the grooves is connected to an edge of the die pad by at least one of the runners; and a plurality of leads formed around the die pad.

The grooves are interconnected to encompass and form an area or a shape corresponding to the shape of the die pad. Each of the grooves is connected to the edge of the die pad by at least one of the runners. In other words, each edge of a bottom surface of the die pad is provided with at least one of the runners that can be connected to the grooves.

Moreover, the grooves have the same depth and width as the runners, and the depth of the runners is half of the thickness of the die pad. Generally, the depth of the runners can be made as 0.05 mm to 0.15 mm, preferably 0.1 mm; and the width of the runners can be 0.03 mm to 0.2 mm, preferably 0.1 mm.

Therefore, by the foregoing arrangement, when a conventional molding process is performed, if excess flashes occur, the runners can guide the flow of flashes and the grooves can accommodate the flashes, such that the flashes may firstly flow along each edge of the die pad into the runners and then fill the grooves. Moreover, since the plurality of runners and grooves are interconnected, the flashes received in the runners and grooves can be evenly distributed without leaking out of the grooves and flashing to the surface of the die pad, such that the flash problem in the prior art can be completely solved by this flash guiding and diversion mechanism.

### BRIEF DESCRIPTION OF THE DRAWINGS

The present invention can be more fully understood by reading the following detailed description of the preferred embodiments, with reference made to the accompanying drawings, wherein:

FIG. 1A (PRIOR ART) is a cross-sectional view of a conventional QFN semiconductor package with flashes;

FIG. 1B (PRIOR ART) is a bottom view of the semiconductor package shown in FIG. 1A;

FIG. 2A (PRIOR ART) is a cross-sectional view of a conventional semiconductor package disclosed in U.S. Pat. No. 6,204,553;

FIG. 2B (PRIOR ART) is a bottom view of the semiconductor package shown in FIG. 2A;

FIGS. 3A and 3B (PRIOR ART) is bottom views of the semiconductor package shown in FIG. 2A with flashes;

FIG. 4A is a cross-sectional view of a semiconductor package according to a preferred embodiment of the present invention;

FIG. 4B is a bottom view of the semiconductor package shown in FIG. 4A;

FIG. 5 is a bottom view of a die pad according to another preferred embodiment of the present invention; and

FIG. 6 is a bottom view of the die pad according to a further preferred embodiment of the present invention.

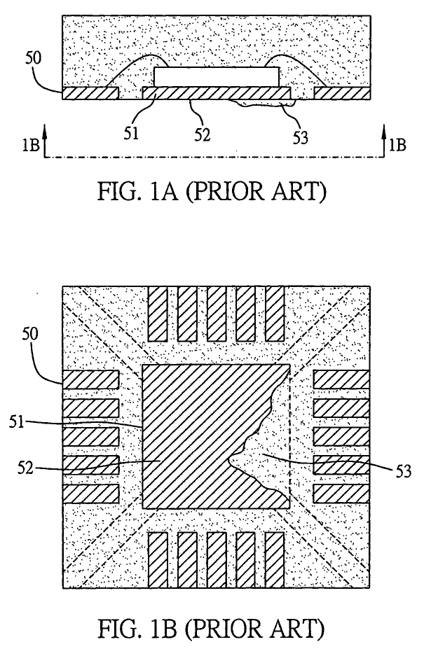

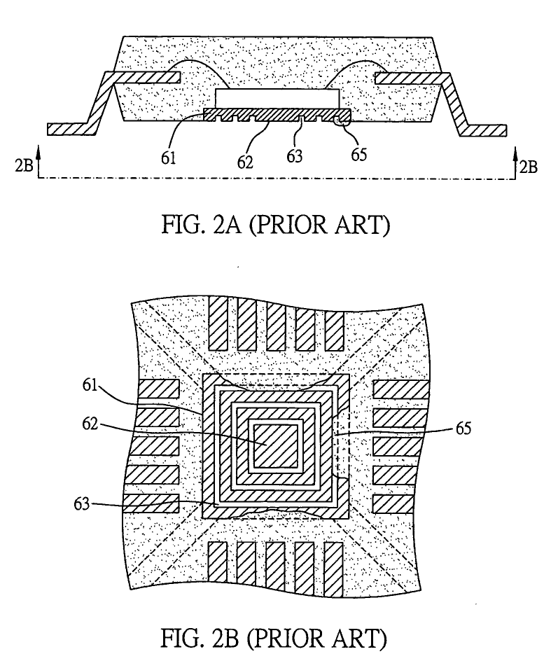

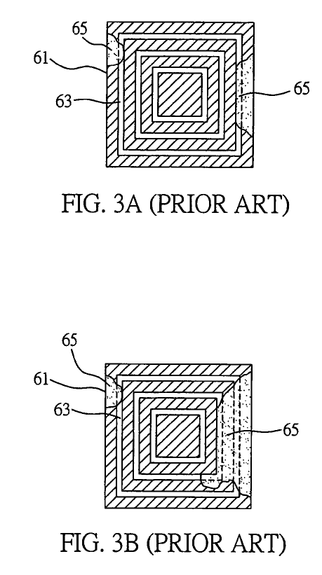

### DETAILED DESCRIPTION OF THE PREFERRED EMBODIMENTS

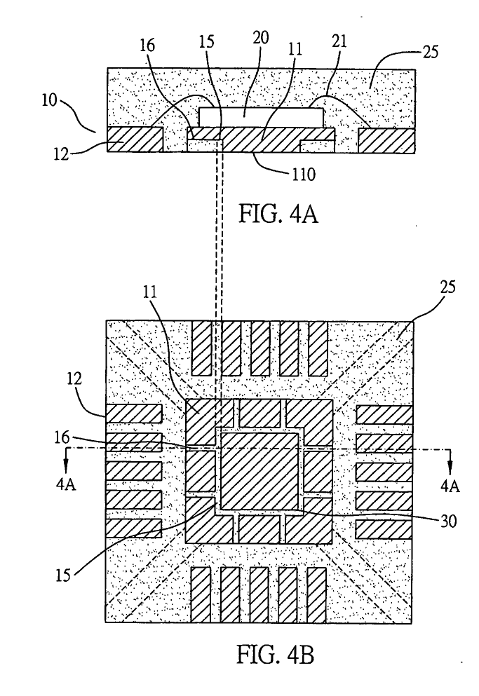

As shown in FIGS. 4A and 4B, a lead-frame-based semiconductor package according to a preferred embodiment of the present invention comprises a lead frame 10 having a square die pad 11 and a plurality of leads 12 around the die pad 11, wherein a plurality of grooves 15 and runners 16 are formed on a bottom surface 110 of the die pad 11. As shown in a bottom view of FIG. 4B, the grooves 15 are interconnected to encompass and form an area or a shape corresponding to the square shape of the die pad 11, and each of the grooves 15 is connected to an edge of the die pad 11 by two of the runners 16. In other words, each edge of the bottom surface 110 of the die pad 11 is provided with at least one of the runners 16 that can be connected to the grooves 15. Each of the runners 16 is extended inwardly from the edge of the die pad 11.

The semiconductor package further comprises a chip 20 mounted on a top surface of the die pad 11, wherein the chip 20 is electrically connected to the plurality of leads 12 by a plurality of bonding wires 21 such as gold wires. Then, an encapsulant 25 can be fabricated by a molding process to encapsulate the chip 20, the bonding wires 21 and a portion of the leads 12, wherein bottom surfaces of the leads 12 and the bottom surface 110 of the die pad 11 are exposed from the encapsulant 25, such that the plurality of grooves 15 and runners 16 are all exposed from the encapsulant 25.

Therefore, by the foregoing arrangement, when a conventional molding process is performed, if flashes 30 occur, the runners 16 can guide the flow of flashes 30 and the grooves 15 can accommodate the flashes 30, such that the flashes 30 may firstly flow along each edge of the die pad 11 into the runners 16 and then fill the grooves 15. Moreover, since the plurality of runners 16 and grooves 15 are interconnected, the flashes 30 received in the runners 16 and grooves 15 can be evenly distributed without leaking out of the grooves 15 and flashing to the surface of the die pad 11, such that the flash problem in the prior art can be completely solved by this flash guiding and diversion mechanism.

The grooves 15 have the same depth and width as the runners 16, and the depth of the runners 16 is half of the thickness of the die pad 11. Generally, the depth of the runners 16 can be made as 0.05 mm to 0.15 mm, preferably 0.1 mm; and the width of the runners 16 can be 0.03 mm to 0.2 mm, preferably 0.1 mm.

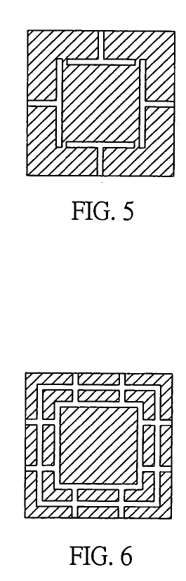

Besides the foregoing embodiment, the grooves 15 and the runners 16 can have other modifications in quantity and location. For example, as shown in FIG. 5 of a bottom view of the die pad 11, all the grooves 15 are not interconnected, and each of the grooves 15 is connected to only one of the runners 16. Alternatively, as shown in a bottom view of FIG. 6, the number of circles encompassed by the grooves 15 is increased to provide larger space for accommodating the flashes 30, thereby yielding a better flash preventing effect.

Accordingly, the lead frame 10 proposed in the present invention comprises at least one die pad 11 formed with a plurality of grooves 15 and runners 16 on a surface thereof, wherein each of the grooves 15 is connected to an edge of the die pad 11 by at least one of the runners 16; and a plurality of leads 12 formed around the die pad 11.

Therefore, the lead-frame-based semiconductor package and the lead frame thereof in the present invention utilize the runners to guide the flow of flashes and thereby improve a flash preventing effect, such that the fabrication cost and processes can be reduced, and the problems encountered in the prior art can be effectively solved.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A lead-frame-based semiconductor package, comprising:
a lead frame having at least one die pad and a plurality of leads around the die pad, wherein a plurality of grooves and runners are formed on a surface of the die pad, and each of the grooves is connected to an edge of the die pad by at least one of the runners;
at least one chip mounted on a surface of the die pad free of having the grooves and runners, and electrically connected to the plurality of leads; and
an encapsulant for encapsulating the chip, with the grooves and runners being exposed from the encapsulant.

2. The lead-frame-based semiconductor package of claim 1, wherein the plurality of grooves encompass an area or a square shape on the surface of the die pad.

3. The lead-frame-based semiconductor package of claim 1, wherein the plurality of grooves are interconnected.

4. The lead-frame-based semiconductor package of claim 1, wherein each of the grooves is connected to two of the runners.

5. The lead-frame-based semiconductor package of claim 1, wherein each of the runners is extended inwardly from the edge of the die pad.

6. The lead-frame-based semiconductor package of claim 1, wherein the runners are for guiding flow of flashes.

7. The lead-frame-based semiconductor package of claim 1, wherein the grooves are for accommodating flashes.

8. The lead-frame-based semiconductor package of claim 1, wherein the grooves have the same depth and width as the runners.

9. The lead-frame-based semiconductor package of claim 8, wherein the depth of the runners is half of the thickness of the die pad.

10. The lead-frame-based semiconductor package of claim 1, wherein the depth of the runners is 0.05 mm to 0.15 mm.

11. The lead-frame-based semiconductor package of claim 10, wherein the depth of the runners is 0.1 mm.

12. The lead-frame-based semiconductor package of claim 1, wherein the width of the runners is 0.03 mm to 0.2 mm.

13. The lead-frame-based semiconductor package of claim 12, wherein the width of the runners is 0.1 mm.

14. A lead frame, comprising:
at least one die pad formed with a plurality of grooves and runners on a surface thereof, wherein each of the grooves is connected to an edge of the die pad by at least one of the runners; and
a plurality of leads formed around the die pad.

15. The lead frame of claim 14, wherein the plurality of grooves encompass an area or a square shape on the surface of the die pad.

16. The lead frame of claim 14, wherein the plurality of grooves are interconnected.

17. The lead frame of claim 14, wherein each of the grooves is connected to two of the runners.

18. The lead frame of claim 14, wherein each of the runners is extended inwardly from the edge of the die pad.

19. The lead frame of claim 14, wherein the runners are for guiding flow of flashes.

20. The lead frame of claim 14, wherein the grooves are for accommodating flashes.

21. The lead frame of claim 14, wherein the grooves have the same depth and width as the runners.

22. The lead frame of claim 21, wherein the depth of the runners is half of the thickness of the die pad.

23. The lead frame of claim 14, wherein the depth of the runners is 0.05 mm to 0.15 mm.

24. The lead frame of claim 23, wherein the depth of the runners is 0.1 mm.

25. The lead frame of claim 14, wherein the width of the runners is 0.03 mm to 0.2 mm.

26. The lead frame of claim 25, wherein the width of the runners is 0.1 mm.
